(19) United States
(12) Patent Application Publication
(10) Pub. No.: US 2005/0188917 A1
(43) Pub. Date: Sep. 1, 2005

(54) Method for manufacturing crystal plate

(76) Inventors: Masaaki Aoshima, Nakano-ku (JP); Hiroaki Aoshima, Nakano-ku (JP)

Correspondence Address: Masaaki Aoshima, 4-34-14 Yayoicho, Nakano-ku, 164-0013, JP

(21) Appl. No.: 10/791,981

(22) Filed: Mar. 1, 2004

(51) Int. Cl. C30B 13/00; C30B 21/04; C30B 28/08; C30B 9/00; C30B 11/00; C30B 17/00; C30B 21/02; C30B 28/06

(52) U.S. Cl. 117/81

(57) ABSTRACT

A method for manufacturing a crystal plate, comprising the steps of adhering one of an amorphous plate and a crystalline body integrally and merging with the amorphous plate and the crystalline body; and separating the amorphous plate from the crystalline body after the crystal structure of the crystalline body is copied to the amorphous plate so that the crystal structure of the crystalline body can be copied to the amorphous plate without the crystal structure in a short time (short period), and it is easy and cheap to form a crystal plate from the amorphous plate.

### BACKGROUND OF THE INVENTION

This invention relates to a method for manufacturing a crystal plate. In particular, the invention relates to manufacture the crystal plate copied the crystal structure of a crystalline body to an amorphous plate. The conventional manufacture method of the artificial crystal is the method of making it raise (growth). Therefore, in order to raise a crystal so that it may grow up like agricultural products if one grain of seed is first planted in a field, the core of a crystal used as one grain of seed, for example, the seed of crystal is chosen, it grows up (accumulation) using the hydrothermal synthesis method, and the bigger single crystal grows.

Various methods are developed in order to raise a single crystal until now. For the method crystallized, they are divided roughly into a growth from melt, growth from solution, growth from the gaseous phase, growth from solid phase, and growth by such combination, and each growth method is a method for raising or growing up into the crystal from the seed.

Therefore, in the period of the growth, in proportion to the size of the crystal, the short object spends in several weeks, and the long object also spends in several months.

Moreover, the direction measurement of a crystal is very important of the conventional main processing processes including the direction measurement, cutting, grinding, polishing, forming, inspecting etc. There are seven systems in the crystal, such as triclinic system, monoclinic system, orthorhombic system, hexagonal system, trigonal system, pyramidal quadratic system and cubic system. In the direction measurement, after the X-rays is incident into the crystal which is chosen by the usage and purpose and diffracted (spots which are scattered and interfered), the direction is measured and detected the unit of inclination, that is, °, ′ and ″ to the principal axis of the detected crystal with high precision.

Therefore, in the direction measurement, the direction as a purpose which the product needs is formed from the various forms (for example, conical shape, six-sided prism and the like) which each crystal has, and the yield is 30% or less by the direction, and there is much futility.

Furthermore, in the processing process that manufactures the crystal, it is requiring continuation of strain and the advanced skill of art. In addition, the damaging in the process is also high average, and the overlapping processing expense is also added.

### SUMMARY OF THE INVENTION

It is an object of the invention to provide a method for manufacturing a crystal plate that the crystal structure of the crystalline body can be copied to the amorphous plate without the crystal structure in a short time (short period).

It is another object of the invention to provide a method for manufacturing a crystal plate that it is easy and cheap to form a crystal plate from the amorphous plate.

It is further object of the invention to provide a method for manufacturing a crystal plate that there is no growth period over a long period, and all the processing processes for making it such as direction measurement after the completion of growth can be abolished.

Novel features which are believed to be characteristic of the invention, both as to its organization and method of operation, together with further objects and advantages thereof, are described below with reference to the accompanying drawings in which preferred embodiments of the invention are illustrated as an example.

It is to be expressly understood, however, that the drawings are for the purpose of illustration and description only, and are not intended as a definition of the limits of the invention.

### BRIEF DESCRIPTION OF THE DRAWINGS

FIG. 1 is a block diagram showing a first embodiment of the present invention;

FIG. 2 is an explanation view of a step for adhering;

FIG. 3 is an explanation view of a step for separating;

FIG. 4 is an explanation view of a crystal showing a crystal structure and axis;

FIG. 5 is an explanation view of the way in which an amorphous plate and crystalline body are adhered;

FIG. 6 is an explanation view of a crystalline plate after coping;

FIG. 7 is a block diagram showing a second embodiment of the present invention;

FIG. 8 is an explanation view of a step for adhering;

FIG. 9 is an explanation view of a step for processing;

FIG. 10 is a block diagram showing a third embodiment of the present invention;

FIG. 11 is an explanation view of a step for separating;

FIG. 12 is a block diagram showing a fourth embodiment of the present invention;

FIG. 13 is an explanation view of a step for separating;

FIG. 14 is a block diagram showing a fifth embodiment of the present invention;

FIG. 15 is an explanation view of a step for separating;

FIG. 16 is a block diagram showing a sixth embodiment of the present invention; and

FIG. 17 is an explanation view of a step for separating.

### DETAILED DESCRIPTION OF THE PREFERRED EMBODIMENTS

Preferred embodiments of the present invention are described in more detail below with reference to the accompanying drawings.

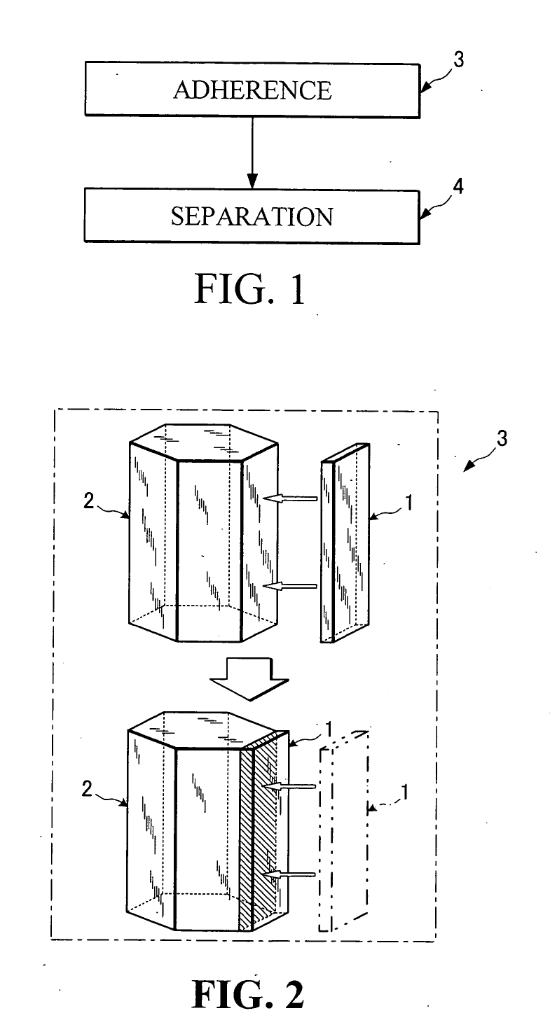

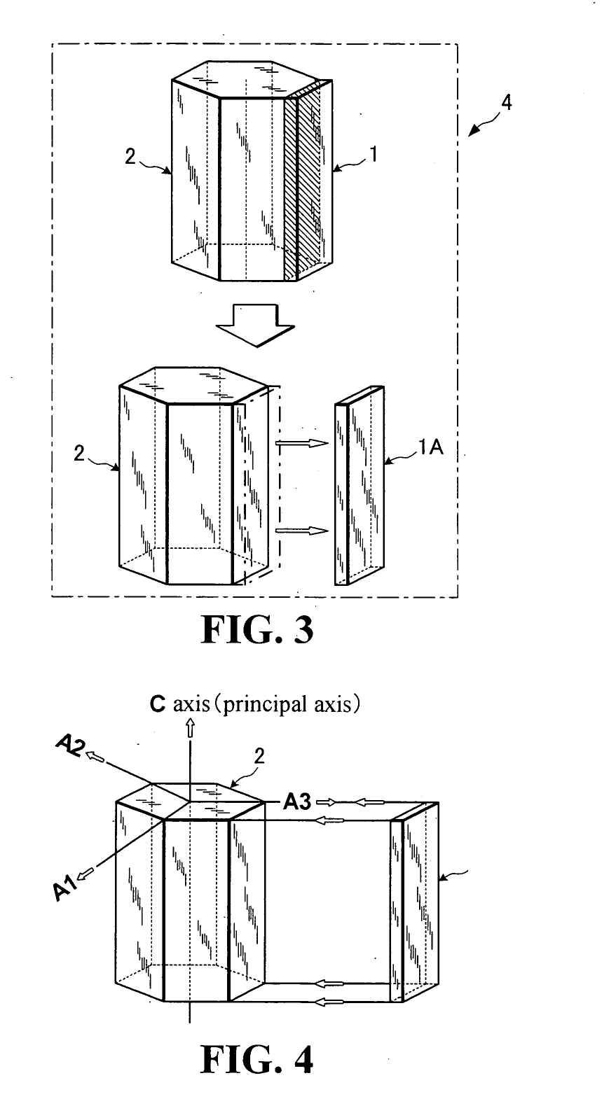

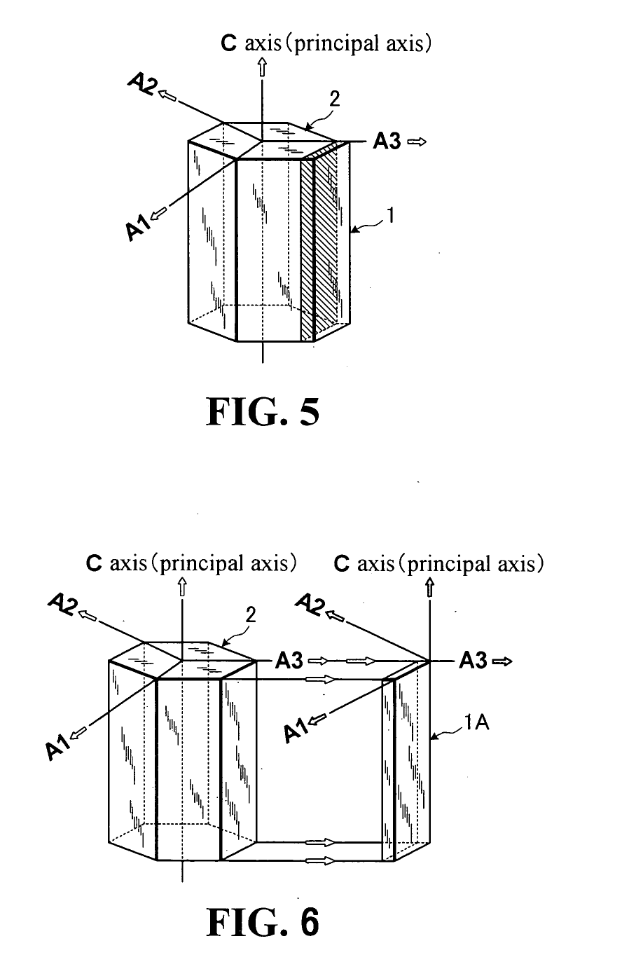

FIGS. 1-6 illustrate a method for manufacturing a crystal plate in accordance with a first embodiment of the present invention. The manufacturing method includes a step 3 for adhering an amorphous plate 1 and a crystalline body 2 integrally or merging with the amorphous plate 1 and the crystalline body 2; and a step 4 for separating the amorphous plate 1 from the crystalline body 2 after the crystal structure of the crystalline body 2 is copied to the amorphous plate 1.

By this method, after the amorphous plate 1 without the crystal structure is induced the crystalline body 2 with the crystal structure and separates, the amorphous plate 1 is set to a crystal plate 1A with the same crystal structure as the crystalline body 2. Here, in this case of the embodiment, the crystal structure chooses and assumes a hexagonal system crystal having A1-axis, A2-axis, A3-axis and C-axis (principal axis) respectively.

In this embodiment, “amorphous” does not have the crystal structure as a space lattice that the atom, ion or molecule arrange with three-dimensional periodicity.

Moreover, “plate” means an object formed in the shape of a plate or board, and the foil or film commonly is also similar to such plate.

The condition which copies the crystal structure used as the basis of the crystalline body 2 to the amorphous plate 1 is that it is the same substance or a different substance having the same system. As an example of the same substance, crystal (single crystal) is used as the crystalline body 2, and silica glass is used as the amorphous plate 1. Silica glass is made of silica dioxide (SiO2) that is the same substance as crystal, not the crystal structure so that the crystal structure of crystal can be copied to silica glass (amorphous).

There are seven systems in the crystal, such as triclinic system, monoclinic system, orthorhombic system, hexagonal system, trigonal system, pyramidal quadratic system and cubic system, as an example having the same system even if it is a different substance.

In this case, the same system means for example, hexagonal system each other, cubic system each other or the like. Specifically, the silicone (Si) of a semiconductor, diamond (C), germanium (germanium) and the like have the same system respectively.

Therefore, if the different substance (for example, diamond and semiconductor silicone) has same system each other, one of the substances becomes the crystalline body 2, and it can copy the crystal structure to another substance.

Then, the transfer of the crystal structure is explained roughly. The unstable state that the schoolboys (an atom and molecule) who are the same grades and had the same uniform on at rest time in a defined field which is the inside of the schoolyard of an elementary school are playing in disorderly fashion (disorderly) as they like will be the amorphous plate 1.

In the present invention, the amorphous plate 1 with the unstable state is attracted, and the kiln 6 which may apply and use the combination of light, heat, electricity etc. is worked. Then, after atom, molecule, ion etc. can be excited at the high-energy state by absorption of radiation, electric discharge and the shock of high-speed particle line etc., and it is easy to happen to the chemical reaction or crystal lattice. Therefore, it can copy the crystal structure and can change it into the completely same state as a crystal. That is, the amorphous plate without the crystal structure is set to the crystal plate with the same crystal structure as the crystalline body.

On the other hand, the stable state (it has the crystal structure) that the schoolboys (an atom and molecule) who are the same grades and had the same uniform and turned to the all the members front in the same schoolyard maintain the fixed interval (having three-dimensional periodicity), line up regularly (arrangement) and connect their hands firmly is the crystalline body 2.

The relation between the crystal axis of the crystal structure as a substrate of the crystalline body 2 and a heat expansion coefficient is explained.

In the character of crystal, there are aeolotropy (physical description of the substance is differ from the direction) and isotropy (physical description of the substance is not differ from the direction).

The form of the hexagonal system with aeolotropy shown in FIG. 1 is a six-sided prism, and the heat expansion coefficient of the direction of C-axis is different from that of the direction of A-axis. Therefore, it generates the irregular crack (separation) accompanying contraction in many cases when the fire extinguishing and cooling (after slow cooling) are carried out after the growth finishes. The cause of the crack (separation) is based on the difference of the heat expansion coefficient by different direction, and the phenomenon of the crack (separation) happens to the crystal having the different directions and the isotropic crystal so that it is the inescapable factor. Therefore, even if it is a crystal (single crystal), the difference (expansion×contraction) of the heat expansion coefficient causes an inescapable crack (separation).

Then, the manufacture method which copies the crystal structure of the crystalline body 2 to the amorphous plate 1 of this invention is used the factor of an inescapable crack (separation) by the difference (expansion×contraction) of this expansion coefficient as the separation intentionally.

As an example of the process utilized as the separation, when the difference (expansion×contraction) of the heat expansion coefficient of the amorphous plate 1 and the crystalline body 2 is small, it separates mutually automatically and easily by carrying out the slow cooling (it returning to normal temperature gently and gradually).

Moreover, it separates also according to the difference of expansion or contraction by warming or cooling.

Moreover, before destroying, it can also be made to separate intentionally in an adjustable kiln (seal furnace) since there is a possibility of destroying (dispersion) in the slow cooling without keeping expansion or contraction when the difference of the expansion coefficient is large.

Therefore, the long growth period, the processing process with highly precise and the badness of the yield by the direction measurement etc. are not relate to manufacture the crystal plate, and it should just copy the crystal structure of the crystalline body to the amorphous plate.

In addition, the crystal structure of the crystalline body 2 may be copied to the amorphous plate 1 so as to copy the picture or take it for example, and it may be copied the crystal structure continuously to the amorphous plate 1 when there is only the crystal structure.

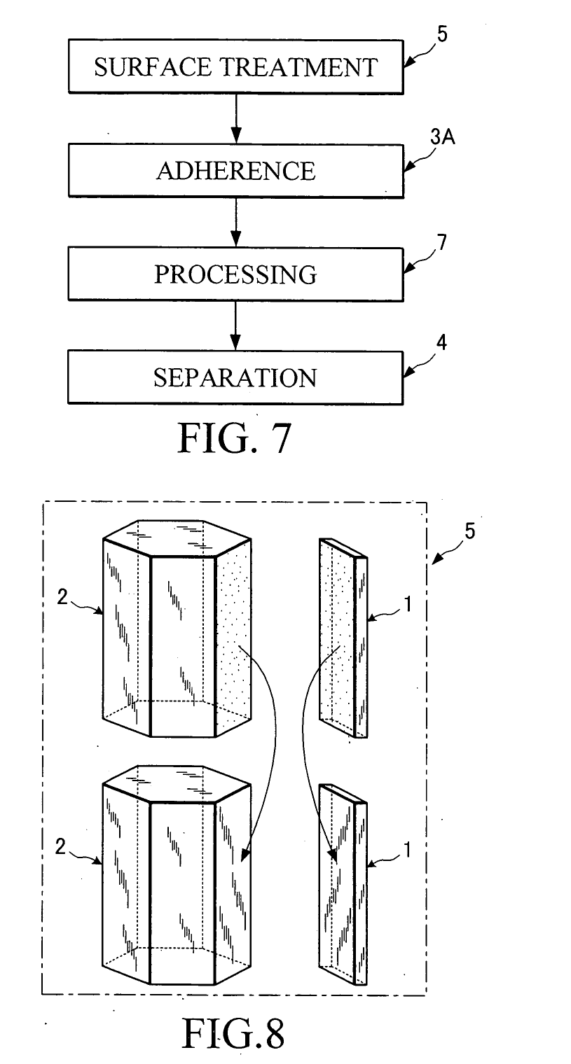

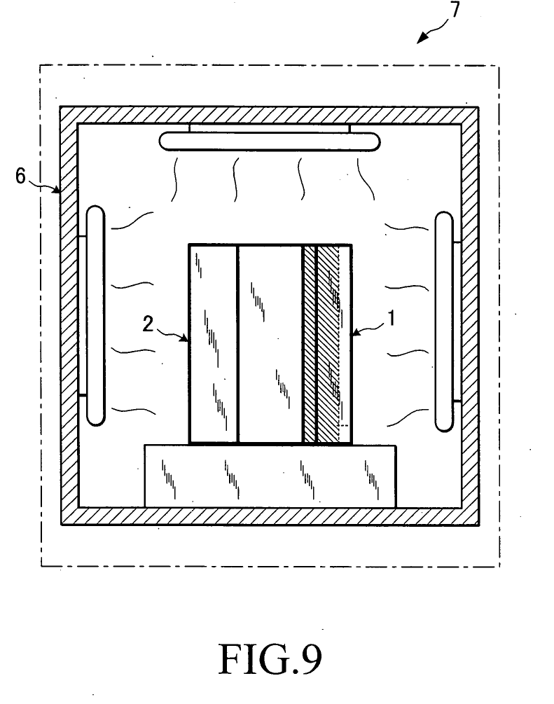

Other embodiments of the present invention will now be described with reference to FIGS. 7-17. In FIGS. 7-17, the same components as in the first embodiment described above with reference to FIGS. 7-17 are designated by the same reference numerals and therefore will not be further explained in great detail.

A second embodiment of the present invention is shown in FIGS. 7-9. It is distinguished from the first embodiment in that a method for manufacturing a crystal plate further includes a step 5 for treating the surface of the amorphous plate 1 and crystalline body 2; a step 3 for adhering the amorphous plate 1 and the crystalline body 2 in or out of an adjustable kiln 6 (furnace) which may apply and use the combination of light, heat, electricity etc. after the treating step 5 is performed; and a step 7 for processing so as to copy the crystal structure of the crystalline body 2 to the amorphous plate 1, heating in this embodiment of the present invention after the adjustable kiln 6 is worked. A method for manufacturing the crystal plate according to the second embodiment has similar advantages to that according to the first embodiment.

In this embodiment, the amorphous plate with the unstable state is attracted, and the kiln 6 is worked and heated at approximately 500 to 3000 degrees C., preferably heated at approximately 2000 degrees C. Then, after atom, molecule, ion etc. can be excited at the high-energy state by absorption of radiation, electric discharge and the shock of high-speed particle line etc., and it is easy to happen to the chemical reaction or crystal lattice. Therefore, it can copy the crystal structure and can change it into the completely same state as a crystal.

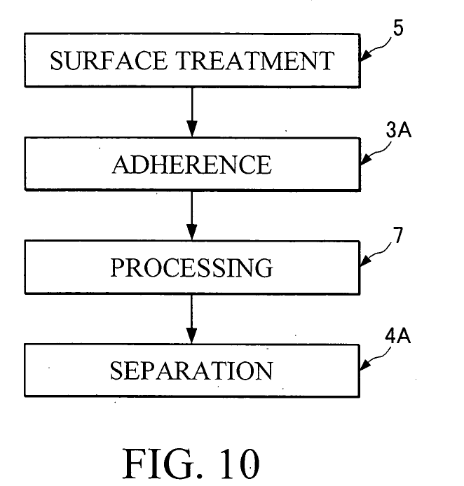

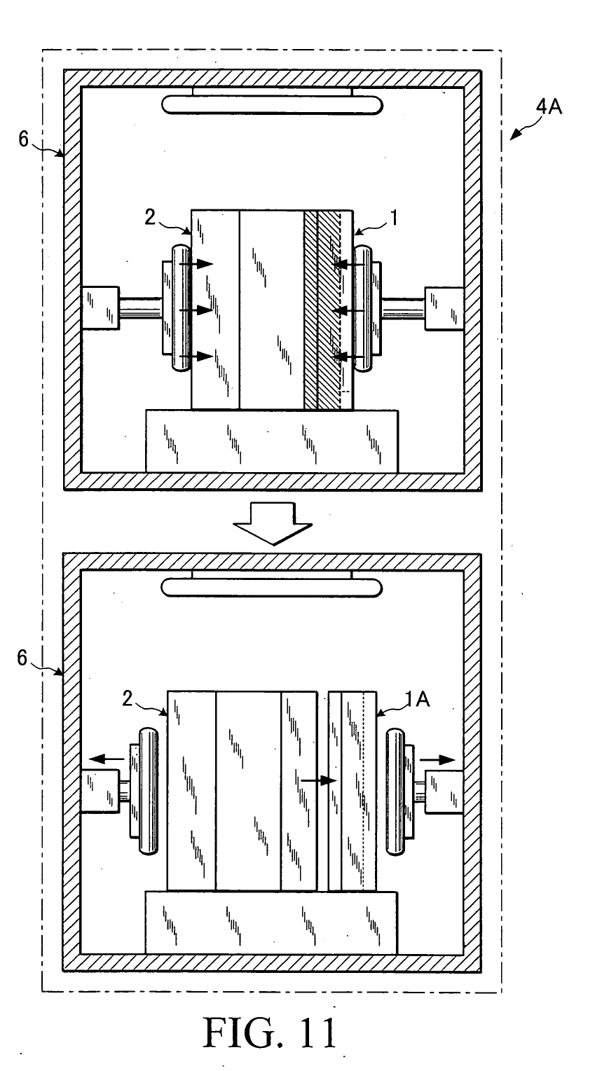

A third embodiment of the present invention is shown in FIGS. 10 and 11. It is distinguished from the second embodiment in that a step 4A for separating the amorphous plate 1 and crystalline body 2 by pressing after the processing step 7 is performed. A method for manufacturing the crystal plate according to the third embodiment has similar advantages to that according to the second embodiment.

Moreover, before destroying, it can also be made to separate intentionally in an adjustable kiln 6 since there is a possibility of destroying (dispersion) in the slow cooling without keeping expansion or contraction when the difference of the expansion coefficient is large.

In addition, in the processing step 7 in this embodiment, the amorphous plate 1 and crystalline body 2 may be pressed as same as the separating step 4A.

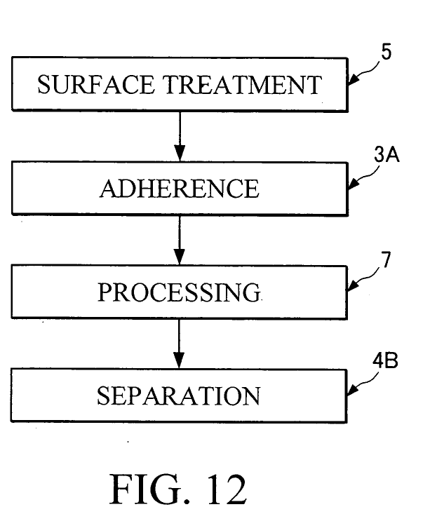

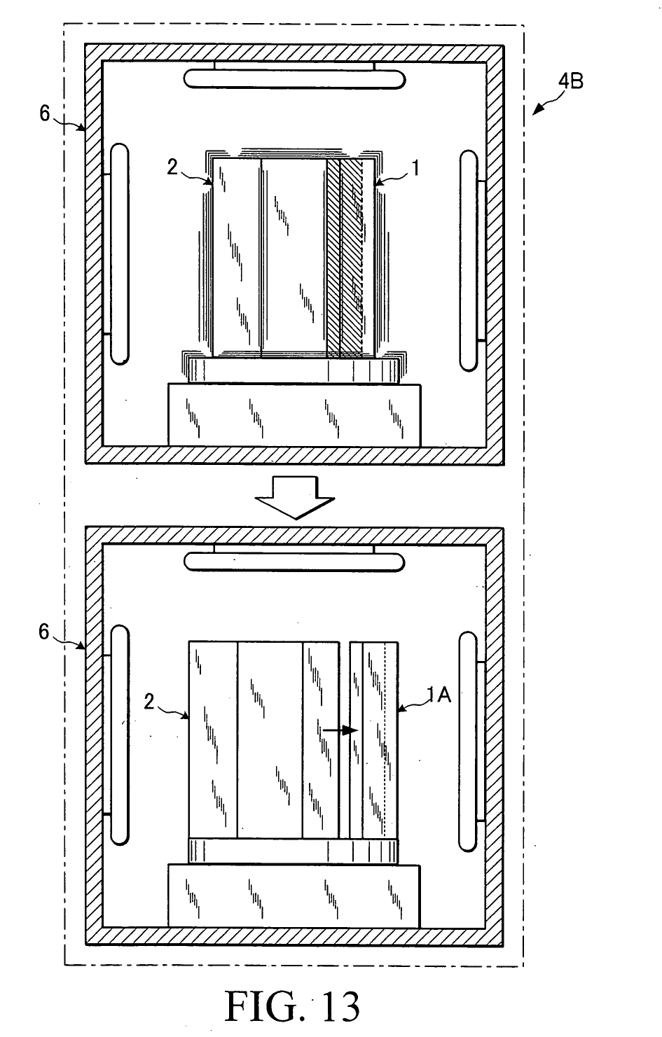

A fourth embodiment of the present invention is shown in FIGS. 12-13. It is distinguished from the second embodiment in that a step 4B for separating the amorphous plate 1 and crystalline body 2 by vibrating with wave motion or oscillating equipment after the processing step 7 is performed. A method for manufacturing the crystal plate according to the fourth embodiment has similar advantages to that according to the second embodiment.

In addition, in the processing step 7 in this embodiment, the amorphous plate 1 and crystalline body 2 may be vibrated as same as the separating step 4B.

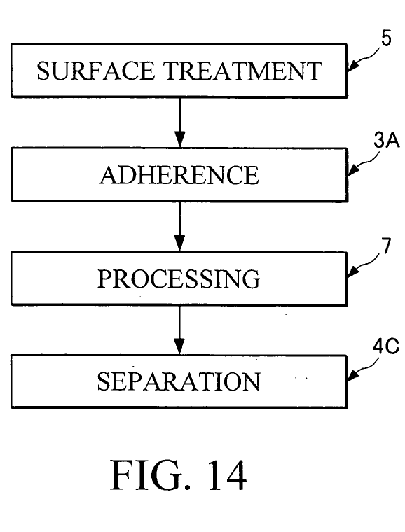

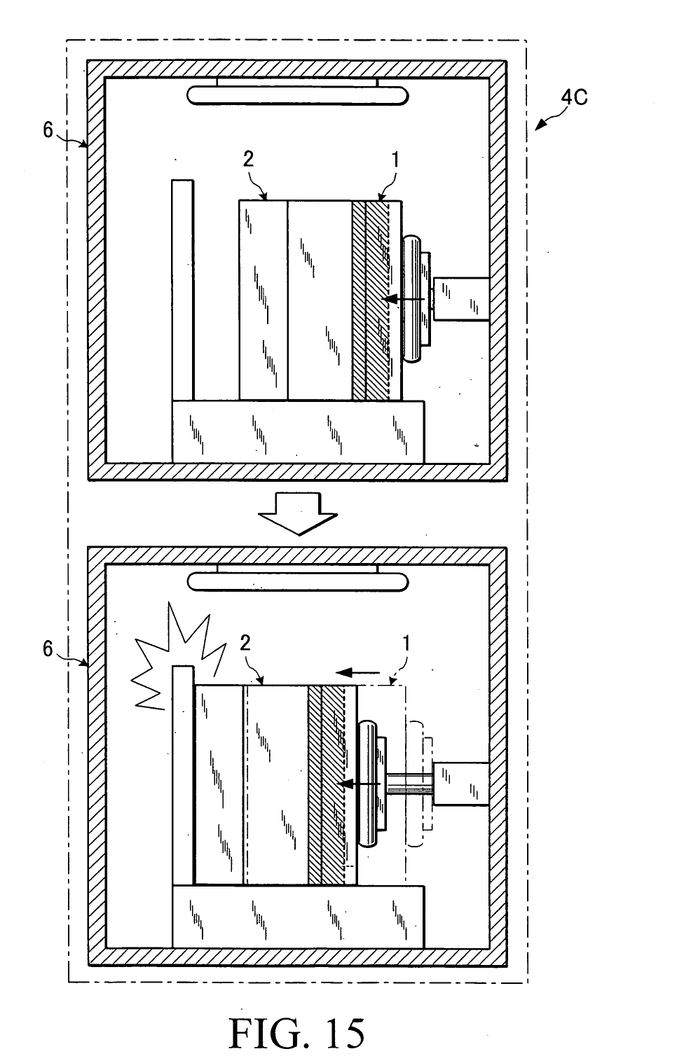

A fifth embodiment of the present invention is shown in FIGS. 14-15. It is distinguished from the second embodiment in that a step 4C for separating the amorphous plate 1 and crystalline body 2 by colliding suitably after the processing step 7 is performed. A method for manufacturing the crystal plate according to the fifth embodiment has similar advantages to that according to the second embodiment.

In addition, in the processing step 7 in this embodiment, the amorphous plate 1 and crystalline body 2 may be collided as same as the separating step 4C.

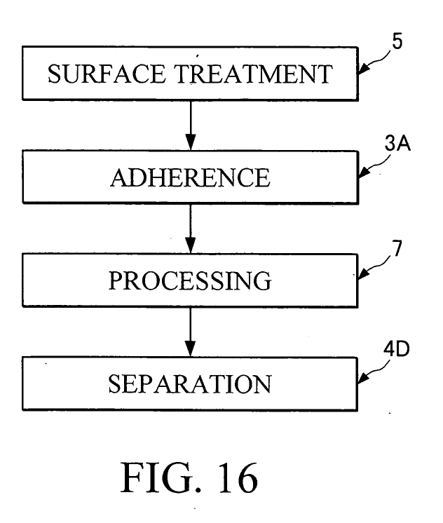

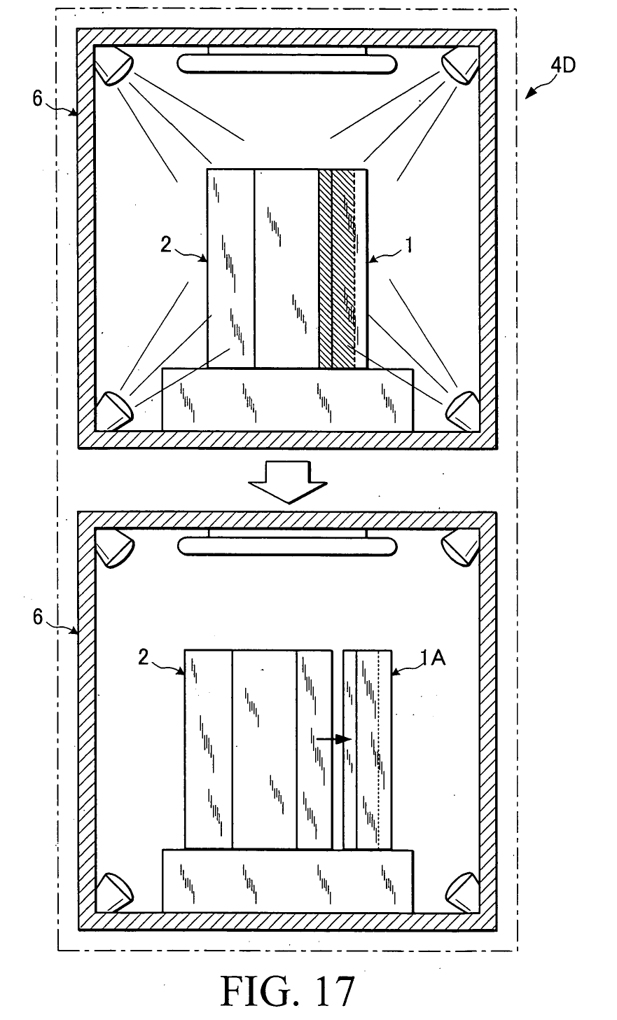

A sixth embodiment of the present invention is shown in FIGS. 16-17. It is distinguished from the second embodiment in that a step 4D for separating the amorphous plate 1 and crystalline body 2 by irradiating an ultraviolet ray, infrared rays, visible light and the like suitably after the processing step 7 is performed. A method for manufacturing the crystal plate according to the sixth embodiment has similar advantages to that according to the second embodiment.

Moreover, in the processing step 7 in this embodiment, the amorphous plate 1 and crystalline body 2 may be irradiated ultraviolet ray, infrared rays, visible light and the like as same as the separating step 4D.

In addition, although the second to sixth embodiments in this invention explain performing various separation processes, it may use the separation process and processing step using a difference of cooling temperature, difference of atmospheric pressure, gas density and the like.

Furthermore, although each embodiment differs mainly explained based on the first embodiment, even if it uses the present invention combining the composition used for the form of not only this but each embodiment, the same action effect is acquired.

As set forth above, the advantages of the invention are as follows:
(1) A method for manufacturing a crystal plate, comprising the steps of adhering one of an amorphous plate and a crystalline body integrally and merging with the amorphous plate and the crystalline body; and separating the amorphous plate from the crystalline body after the crystal structure of the crystalline body is copied to the amorphous plate so that the long growth period, the processing process with highly precise and the badness of the yield by the direction measurement and the like are not relate to manufacture the crystal plate, and it should just copy the crystal structure of the crystalline body to the amorphous plate.

In addition, the crystal structure of the crystalline body may be copied to the amorphous plate so as to copy the picture or take it for example, and it may be copied the crystal structure continuously to the amorphous plate 1 when there is only the crystal structure.

Therefore, it is easy and cheap to manufacture the crystal plate from the amorphous plate.

1. A method for manufacturing a crystal plate, comprising the steps of:
adhering one of an amorphous plate and a crystalline body integrally and merging with the amorphous plate and the crystalline body; and
separating the amorphous plate from the crystalline body after the crystal structure of the crystalline body is copied to the amorphous plate.

2. A method for manufacturing a crystal plate, comprising the steps of:
treating a surface of an amorphous plate and a crystalline body;
adhering the amorphous plate and the crystalline body one of inside or outside of an adjustable kiln which applies and uses the combination of light, heat, electricity after the treating step is performed;
processing so as to copy a crystal structure of the crystalline body to the amorphous plate after the adjustable kiln is worked; and
separating the amorphous plate from the crystalline body.

3. The method of claim 2 wherein the step of processing includes that the amorphous plate with an unstable state is attracted, and the adjustable kiln works and heated at approximately 500 to 3000° C.

4. The method of any one of claims 1 and 2 wherein the step of separating includes that the amorphous plate and crystalline body are pressed after the processing step is performed

5. The method of any one of claims 1 and 2 wherein the step of separating includes that the amorphous plate and crystalline body are vibrated with one of a wave motion and an oscillating equipment after the processing step is performed.

6. The method of any one of claims 1 and 2 wherein the step of separating includes that the amorphous plate and crystalline body are collided suitably after the processing step is performed.

7. The method of any one of claims 1 and 2 wherein the step of separating includes that the amorphous plate and crystalline body are irradiated one of an ultraviolet ray, infrared rays and visible light suitably after the processing step is performed.
